(19) United States
(12) Patent Application Publication
(10) Pub. No.: US 2025/0294671 A1
(43) Pub. Date: Sep. 18, 2025

(54) PRINTED CIRCUIT BOARD AND ELECTRONIC CONTROL DEVICE

(71) Applicant: DENSO CORPORATION, Kariya-city (JP)

(72) Inventor: Yasunari TANIMURA, Kariya-city (JP)

(21) Appl. No.: 18/970,201

(22) Filed: Dec. 5, 2024

(30) Foreign Application Priority Data
Mar. 15, 2024 (JP) 2024-041616

(51) Int. Cl. H05K 1/02; H05K 1/11

(52) U.S. Cl. CPC H05K 1/0296; H05K 1/115

(57) ABSTRACT

A printed circuit board includes an insulating substrate and a power supply pattern which is part of a conductive wiring portion and is provided on at least one surface of the insulating substrate. The printed circuit board has an insulating portion on one surface where no power supply pattern is formed, and a terminal land which is a portion to which solder is connected and which is partly connected to the power supply pattern and partly adjacent to the insulating portion. The printed circuit board is surrounded by the insulating portion and includes a conductive extension pattern that extends from the terminal land.

### CROSS REFERENCE TO RELATED APPLICATIONS

This application is based on Japanese Application No. 2024-41616 filed on Mar. 15, 2024, the contents of which are incorporated herein by reference.

### TECHNICAL FIELD

The present disclosure relates to a printed circuit board and an electronic control device.

### BACKGROUND

A printed circuit board is provided with a thermal land having at least half of the periphery of a through hole covered with a solid pattern.

### SUMMARY

One disclosed object is to provide a printed circuit board having improved solder connection reliability. Another disclosed object is to provide an electronic control device having improved solder connection reliability.

A printed circuit board disclosed herein includes
an insulating substrate,
a solid pattern which is a part of a conductive wiring portion and is provided on at least one surface of the insulating substrate,
a non-formed portion on one surface where no solid pattern is formed,
an electrode connection portion which is a portion to which the solder is connected, a portion of which is connected to the solid pattern and another portion of which is adjacent to the non-formed portion, and
a conductive extension pattern which is surrounded by the non-formed portion and extends from the electrode connection portion.

### BRIEF DESCRIPTION OF DRAWINGS

FIG. 1 is a plan view illustrating a schematic configuration of an electronic control device according to a first embodiment;

FIG. 2 is a cross-sectional view taken along a line II-II of FIG. 1;

FIG. 3 is an enlarged plan view of a part III in FIG. 1;

FIG. 4 is a plan view showing a schematic configuration of an electronic control device according to a first modified example;

FIG. 5 is a plan view showing a schematic configuration of an electronic control device according to a second modified example;

FIG. 6 is a plan view showing a schematic configuration of an electronic control device according to a third modified example;

FIG. 7 is a cross-section view along a line VII-VII in FIG. 6;

FIG. 8 is a cross-sectional view showing a schematic configuration of an electronic control device according to a second embodiment; and

FIG. 9 is a partial plan view showing a schematic configuration of an electronic control device according to a second embodiment.

### DETAILED DESCRIPTION

In an assumable example, the printed circuit board is provided with a thermal land having at least half of the periphery of a through hole covered with a solid pattern. The thermal land is composed of a solid pattern, a plurality of bridge circuit portions that connect the solid pattern and the through hole, and a thermal gap portion.

However, the thermal land has the bridges that connect directly to the solid pattern. Therefore, in the printed circuit board, heat generated during soldering dissipates into the solid pattern. Therefore, the solderability of the printed circuit board may deteriorate, which may reduce the reliability of the solder connection. Furthermore, in the above respects and in other respects not mentioned above, further improvements are required in the printed circuit board and the electronic control device.

One disclosed object is to provide a printed circuit board having improved solder connection reliability. Another disclosed object is to provide an electronic control device having improved solder connection reliability.

A printed circuit board disclosed herein includes an insulating substrate, a solid pattern which is a part of a conductive wiring portion and is provided on at least one surface of the insulating substrate, a non-formed portion on one surface where no solid pattern is formed, an electrode connection portion which is a portion to which the solder is connected, a portion of which is connected to the solid pattern and another portion of which is adjacent to the non-formed portion, and a conductive extension pattern which is surrounded by the non-formed portion and extends from the electrode connection portion.

The printed circuit board disclosed therein has an electrode connection portion, a part of which is continuous with the solid pattern and another part of which is provided adjacent to the non-formed portion. The extension pattern extending from the electrode connection portion is surrounded by the non-formed portion. Therefore, the extension pattern is heated when soldering to the electrode connection portion, and the heat is difficult to escape to the solid pattern. Therefore, the printed circuit board can suppress deterioration of solderability and improve the reliability of solder connections.

The electronic control device disclosed herein includes a printed circuit board and an electronic component mounted on the printed circuit board.

The printed circuit board includes an insulating substrate, a solid pattern which is a part of a conductive wiring portion and is provided on at least one surface of the insulating substrate, a non-formed portion on one surface where no solid pattern is formed, an electrode connection portion which is a portion to which the solder is connected, a portion of which is connected to the solid pattern and another portion of which is adjacent to the non-formed portion, and a conductive extension patterns which is surrounded by the non-formed portion and extends from the electrode connection portion.

The electronic component is electrically connected to a wiring portion.

Thus, the electronic control device includes the above-mentioned printed circuit board. Therefore, the reliability of the solder connections in the electronic control device is improved.

The disclosed aspects in this specification adopt different technical solutions from each other in order to achieve their respective objectives. The objects, features, and advantages disclosed in this specification will become apparent by referring to following detailed descriptions and accompanying drawings.

Hereinafter, multiple embodiments of the present disclosure will be described with reference to the drawings. In each embodiment, portions corresponding to those described in the preceding embodiment are denoted by the same reference numerals, and redundant descriptions will be omitted in some cases. In each of the embodiments, when only a part of the configuration is explained, the other part of the embodiment can be referred to the other embodiment explained previously and applied.

Hereinafter, three directions perpendicular to each other are denoted as an X direction, a Y direction, and a Z direction. A plane defined by the X direction and the Y direction is denoted as an XY plane.

### First Embodiment

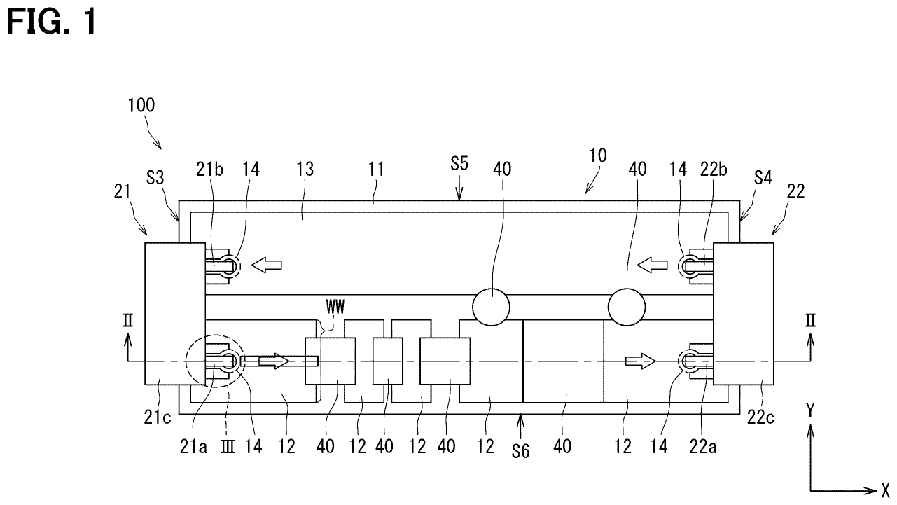

A printed circuit board 10 according to the present embodiment and an electronic control device 100 including the printed circuit board 10 will be described with reference to FIGS. 1 to 3.

Electronic control device 100:

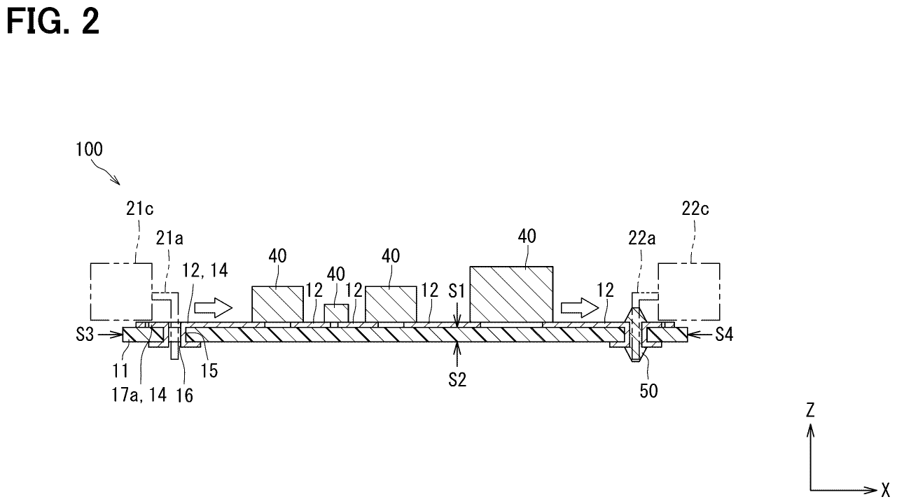

As shown in FIGS. 1 and 2, the electronic control device 100 includes a printed circuit board 10, a power connector 21, an external connector 22, and electronic components 40. Furthermore, the electronic control device 100 may be provided with a housing for housing them. The printed circuit board 10 will be described later. The structure in which the connectors 21, 22 and the electronic components 40 are mounted on the printed circuit board 10 can also be called a circuit board or a printed circuit board.

The power connector 21 is mounted on the printed circuit board 10. The power connector 21 is a connector for electrically connecting the electronic control device 100 to a power supply device provided outside the electronic control device 100. The power supply device is a device that supplies operating power and the like to the electronic components 40.

The power connector 21 includes, for example, a power supply terminal 21a, a ground terminal 21b, and a connector case 21c. The connector case 21c holds the power supply terminal 21a and the ground terminal 21b so that both ends of the power supply terminal 21a and both ends of the ground terminal 21b are exposed. Both terminals 21a, 21b are electrically connected to the wiring portion of the printed circuit board 10 via conductive connecting members. The conductive connecting members may be solder, silver paste, or the like.

The external connector 22 is mounted on the printed circuit board 10. The external connector 22 is a connector for electrically connecting the electronic control device 100 to a load device provided outside the electronic control device 100. The load device is a device whose drive is controlled by the electronic control device 100.

The external connector 22 includes, for example, a power supply terminal 22a, a ground terminal 22b, and a connector case 22c. The connector case 22c holds the power supply terminal 22a and the ground terminal 22b such that both ends of the power supply terminal 22a and both ends of the ground terminal 22b are exposed. Both terminals 22a, 22b are electrically connected to the wiring portion of the printed circuit board 10 via conductive connecting members.

The power connector 21 and the external connector 22 correspond to insertion-mounted components. The terminals 21a, 21b, 22a, and 22b correspond to terminals of the insertion-mounted components. In FIG. 2, in order to simplify the drawing, the connector cases 21c, 22c and the power supply terminals 21a, 22a are shown by two-dot chain lines.

The electronic components 40 are mounted on the printed circuit board 10. The electronic component 40 is a component that constitutes an electronic circuit together with the wiring portion of the printed circuit board 10. A plurality of electronic components 40 are mounted on the printed circuit board 10. In other words, the electronic control device 100 includes a plurality of electronic components 40. The terminals of the electronic component 40 are electrically connected to the wiring portion of the printed circuit board 10 via conductive connecting members. The electronic component 40 can also be considered a circuit element or a circuit device.

The electronic components 40 include a switching element, a resistor element, a capacitor element, a coil, and the like. The switching element is a semiconductor switching element such as a MOSFET or an IGBT. One of the electronic components 40 may be a drive circuit that outputs a drive signal to an external load. One of the electronic components 40 may be a power supply circuit that generates internal power for the electronic control device 100 from power supplied from a power supply device. Incidentally, the printed circuit board 10 may have a drive circuit and a power supply circuit mounted thereon as the electronic components 40.

In the present embodiment, as an example, a surface-mounted type electronic component 40 is used. However, the present embodiment may not be limited to the above example, the present embodiment may adopt, for example, an insertion-mounted component 40. The surface-mounted type electronic component 40 is also called an SMD 40. SMD is an abbreviation for Surface Mount Device. The insertion-mounted type electronic component 40 is also referred to as a THD 40. THD is an abbreviation for Through Hole Device.

Printed circuit board 10:

Here, the printed circuit board 10 will be described with reference to FIGS. 1, 2, and 3. The printed circuit board 10 includes an electrically insulating substrate 11 and conductive wiring portions 12 to 15 and 17a.

As shown in FIGS. 1 and 2, the insulating substrate 11 has a front surface S1 and a back surface S2 opposite to the front surface S1. The front surface S1 and the back surface S2 are flat surfaces along the XY plane. The insulating substrate 11 has four side surfaces S3 to S6. The side surfaces S3 to S6 are surfaces that are continuous with the front surface S1 and the back surface S2. The first side surface S3 and the second side surface S4 are surfaces facing each other. The third side surface S5 and the fourth side surface S6 are surfaces facing each other.

The wiring portions 12 to 15, 17a include the wiring patterns 12 to 14, 17a formed by patterning a conductive thin film (such as copper foil), and an interlayer connection portion 15 formed in a through hole 16 by plating or the like.

As shown in FIG. 2, the through hole 16 is a hole formed in the insulating substrate 11 from the front surface S1 to the back surface S2. The through hole 16 is a hole that constitutes a through hole. The insulating substrate 11 has the interlayer connection portion 15 formed on the surface that defines the through hole 16. The interlayer connection portion 15 is connected to a terminal land 14 formed on the front surface S1. The interlayer connection portion 15 can also be called a through electrode portion. The terminal lands 14 will be described later.

The through hole includes the terminal land 14, the interlayer connection portion 15, and the through hole 16. The through holes are electrodes for connectors 21 and 22 which are the insertion-mounted components. That is, the terminals 21a, 21b, 22a, and 22b of the connectors 21, 22 are inserted into the through holes 16. The terminals 21a, 21b, 22a, and 22b are electrically connected to the terminal lands 14 and the interlayer connection portion 15 by the solder 50.

In the present embodiment, an example is adopted in which through holes are formed in two locations for the power supply pattern 12 and two locations for the ground pattern 13, which will be described later. Furthermore, the printed circuit board 10 may have a through hole for the THD 40 formed therein.

In FIG. 2, in order to simplify the drawing, the solder 50 is shown only on the power supply terminal 22a side. However, the solder 50 is provided corresponding to each of the terminals 21a, 21b, 22a, and 22b. Thus, the solder 50 is connected to each of the through holes.

As shown in FIGS. 1 and 2, the power supply pattern 12 is provided on at least front surface S1 of the insulating substrate 11. The power supply pattern 12 is a wiring pattern for flowing a current. Therefore, the power supply pattern 12 can also be considered as a wiring pattern for supplying current. The power supply pattern 12 is a wiring pattern to which the power supply terminals 21a and 22a are electrically connected.

A plurality of power supply patterns 12 are formed on the front surface S1. The power supply pattern 12 is electrically connected to a terminal of the electronic component 40. Adjacent power supply patterns 12 are electrically connected via the electronic component 40.

As shown in FIG. 1, the ground pattern 13 is provided on at least front surface S1 of the insulating substrate 11. The ground pattern 13, like the power supply pattern 12, is a wiring pattern for flowing a current. Therefore, the ground pattern 13 can also be considered as a wiring pattern for electric current. The ground pattern 13 is a wiring pattern to which the ground terminals 21b and 22b are electrically connected.

The white arrows in FIGS. 1 to 3 roughly indicate the directions of currents (current direction). That is, in the power supply pattern 12, current flows from the power supply terminal 21a toward the electronic component 40. In addition, in the power supply pattern 12, current flows from the electronic component 40 toward the power supply terminal 22a. On the other hand, in the ground pattern 13, current flows from the ground terminal 22b toward the ground terminal 21b.

The power supply pattern 12 and the ground pattern 13 correspond to solid patterns. The solid pattern is a part of the wiring portion. The solid pattern is a wiring pattern that is painted solid. The power supply pattern 12 and the ground pattern 13 are wiring patterns having an area larger than that of a terminal land 14, which will be described later. The power supply pattern 12 and the ground pattern 13 are wiring patterns for flowing a large current. The power supply pattern 12 and the ground pattern 13 are wiring patterns having a larger area than the signal wiring, that is, are wide wiring patterns. The signal wiring is, for example, a wiring pattern connected to the gate electrode of a MOSFET. Hereinafter, the power supply pattern 12 and the ground pattern 13 are collectively referred to as a solid pattern.

As shown in FIGS. 1 to 3, the printed circuit board 10 has an insulating portion 18 on the front surface S1 where the power supply pattern 12 and the ground pattern 13 are not formed. The insulating portion 18 is formed by patterning the power supply pattern 12 and the ground pattern 13 so that the front surface S1 is exposed. The insulating portion 18 is provided around the terminal land 14, which will be described later.

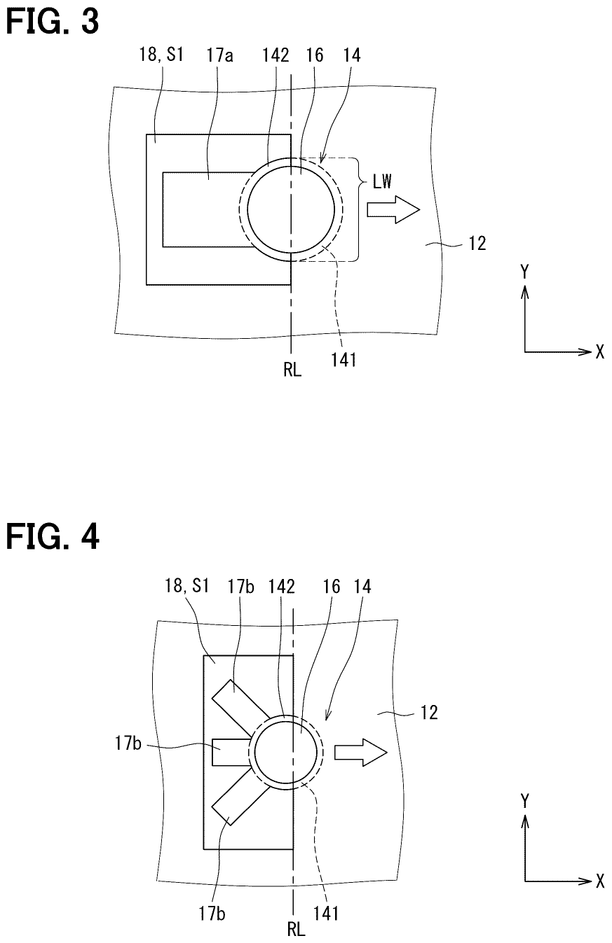

The insulating portion 18 is provided to improve the solderability at the terminal land 14. In other words, the insulating portion 18 is provided to prevent heat during soldering from escaping from the terminal land 14 to the solid pattern. The insulating portion 18 corresponds to a non-formed portion. The insulating portion 18 can also be considered as an area where the solid pattern is removed. A reference line RL in FIG. 3 is an imaginary line indicating the boundary between the power supply pattern 12 and the insulating portion 18.

As shown in FIGS. 1, 2 and 3, the power supply pattern 12 and the ground pattern 13 are each provided with a terminal land 14 in series. In other words, the terminal land 14 is a wiring pattern that is continuous with the power supply pattern 12 and the ground pattern 13, respectively. The terminal land 14 is a portion to which the solder 50 is connected. In the present embodiment, as an example, an example is adopted in which two terminal lands 14 for the power supply pattern 12 and two terminal lands 14 for the ground pattern 13 are provided. In the following, a description will be given using the terminal land 14 to which the power supply terminal 21a is connected.

As shown in FIG. 3, the terminal land 14 is provided in a ring shape around the through hole 16. A portion of the terminal land 14 is connected to the power supply pattern 12 in series. Furthermore, another portion of the terminal land 14 is provided adjacent to the insulating portion 18. The terminal land 14 corresponds to an electrode connection portion. The terminal land 14 can also be referred to as a through-hole land.

The terminal land 14 can be divided into a communication portion 141 and an insulating side portion 142 with the reference line RL as the boundary. The communication portion 141 is a portion that is connected to the power supply pattern 12 in series. The communication portion 141 is a portion on the power supply pattern 12 side with respect to the reference line RL. In addition, the communication portion 141 can be said to be a portion on the electronic component 40 side with respect to the reference line RL. The communication portion 141 can also be considered as a part of the power supply pattern 12.

The insulating side portion 142 is adjacent to the insulating portion 18. The insulating side portion 142 is a portion on the insulating portion 18 side with respect to the reference line RL. The insulating side portion 142 can also be said to be a portion on the opposite side of the reference line RL from the electronic component 40. The insulating side portion 142 can also be considered as a portion extended from the power supply pattern 12. Adjacent means adjacent when viewed on the XY plane as in FIG. 3.

The extension pattern 17a is a wiring pattern that is surrounded by the insulating portion 18 and extends from the terminal land 14. A portion of the extension pattern 17a is continuous with the insulating side portion 142. Moreover, the extension pattern 17a is not in direct contact with the power supply pattern 12. It can be said that the extension pattern 17a extends from the terminal land 14 to a position where it is not connected to the power supply pattern 12. In other words, the extension pattern 17a is a portion separated from the power supply pattern 12. The extension pattern 17a is provided on the insulating portion 18 without connecting the terminal land 14 and the power supply pattern 12. In the present embodiment, as an example, a rectangular extension pattern 17a is used. However, the present disclosure is not only limited to the above example.

The terminal land 14 on the ground pattern 13 side can be divided into the communication portion 141 and the insulating side portion 142 in the same manner as described above. Furthermore, the extension pattern 17a is provided in a continuous manner on the terminal land 14 on the ground pattern 13 side. In this case, the communication portion 141 is a portion on the ground pattern 13 side with respect to the reference line RL. The insulating side portion 142 is a portion on the insulating portion 18 side with respect to the reference line RL. The communication portion 141 can also be considered as a part of the ground pattern 13. The insulating side portion 142 can also be considered as a portion extended from the ground pattern 13. The extension pattern 17a is not in direct contact with the ground pattern 13.

Here, a positional relationship between the power supply pattern 12, the terminal land 14, and the insulating portion 18 will be described. As shown in FIG. 1, the power supply pattern 12 is provided closer to the electronic component 40 than the terminal land 14. In other words, most of the power supply pattern 12 is provided closer to the electronic component 40 than the terminal land 14. The insulating portion 18 is provided on the opposite side of the terminal land 14 from the electronic component 40. Therefore, in the current direction, the insulating portion 18, the terminal land 14, and the power supply pattern 12 are arranged in this order. In the printed circuit board 10, the extension pattern 17a is provided on the insulating portion 18 arranged in this manner.

Therefore, when a current is passed through the solid pattern, the current density of the terminal land 14 is higher in the communicating portion 141 than in the insulating side portion 142. Considering the direction of current flow, the printed circuit board 10 is provided with a wiring pattern such that the communicating portion 141 with a high current density is connected to the solid pattern, and the insulating side portion 142 with a low current density is not in direct contact with the solid pattern.

Next, the width of the solid pattern and the terminal land 14 will be described. The width here refers to the width (length) in the Y direction. As shown in FIGS. 1 and 3, the width WW of the solid pattern is wider than the width LW of the terminal land 14. The width LW of the terminal land 14 is the width of the portion of the terminal land 14 that is continuous with the solid pattern. This allows current to flow easily between the terminal lands 14 and the solid pattern on the printed circuit board 10. The width LW of the terminal land 14 is preferably set to a value that does not adversely affect the insulating portion 18 due to the heat generated by the terminal land 14 when a current is flowed through the solid pattern.

### Effect:

As described above, the printed circuit board 10 includes the terminal lands 14, a portion of which is continuous with the solid pattern and another portion of which is provided adjacent to the insulating portion 18. The extension pattern 17a extending from the terminal land 14 is surrounded by the insulating portion 18. Therefore, the extension pattern 17a is heated when soldering to the terminal land 14, and the heat is unlikely to escape to the solid pattern. Moreover, the heat of the extension pattern 17a is transferred to the terminal land 14.

Therefore, the printed circuit board 10 can suppress a drop in temperature of the terminal lands 14 and further the interlayer connection portion 15 during soldering. Therefore, the printed circuit board 10 can suppress deterioration of the solderability, and can improve the connection reliability of the solder 50. In other words, the printed circuit board 10 can improve the connection reliability of the solder 50 compared to a configuration (comparative example) that includes a thermal land in which the terminal land 14 and the solid pattern are connected via a bridge.

Furthermore, in the comparative example, current flows through the bridge. Therefore, in the comparative example, heat is generated in the bridge. In particular, when a large current flows through the solid pattern, the temperature rise in the bridge is significant. Therefore, in the comparative example, when the glass transition temperature of the insulating base material is exceeded, the reliability and quality of the printed circuit board is reduced.

In contrast, the printed circuit board 10 is different from the bridge and the communication portion 141 is connected to the solid pattern in series. Therefore, in the printed circuit board 10, the width of the communication portion 141 where the current density is high is wider than that of the comparative example. Therefore, the printed circuit board 10 can suppress heat generation due to current flow, and deterioration in the reliability and quality of the printed circuit board 10 can be suppressed. In this way, the printed circuit board 10 can simultaneously suppress heat generation due to current flow and improve the connection reliability of the solder 50.

The electronic control device 100 further includes such a printed circuit board 10 and the electronic components 40 mounted on the printed circuit board 10. Therefore, the electronic control device 100 has improved connection reliability of the solder 50. Furthermore, the electronic control device 100 can suppress heat generation due to current flow.

The preferred embodiments of the present disclosure have been described above. However, the present disclosure is not limited to the above embodiments at all, and various modifications can be made without departing from the gist of the present disclosure. Hereinafter, as other embodiments of the present disclosure, first to third modified examples and a second embodiment will be described. The above-described embodiment, the first to third modified examples, and the second embodiment can be implemented independently, or can be implemented in appropriate combination. The present disclosure is not limited to the combinations illustrated in the embodiments, and can be implemented by various combinations.

### First Modified Example

As shown in FIG. 4, the printed circuit board 10 may have a plurality of extension patterns 17b extending from the terminal land 14. Furthermore, the plurality of extension patterns 17b may be provided in a radial manner. Furthermore, the extension pattern 17b may be provided in a curved shape.

### Second Modified Example

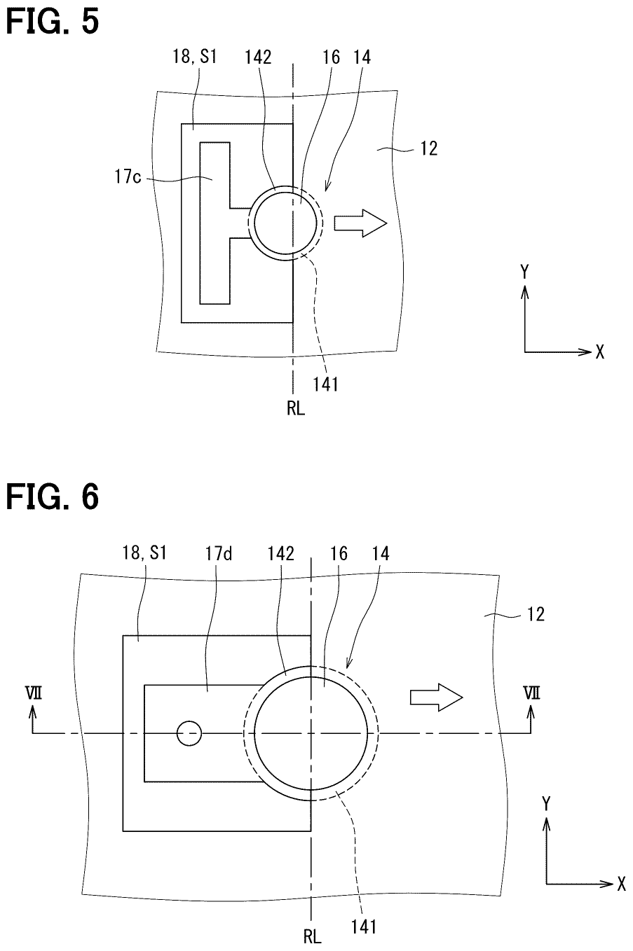

As shown in FIG. 5, the printed circuit board 10 may be provided with a T-shaped extension pattern 17c. In other words, the extension pattern 17c includes a first portion that is provided linearly from the insulating side portion 142 and a second portion that is perpendicular to the first portion.

The extension patterns 17a to 17c are formed in the insulating portion 18 as described above. The shape and area of the insulating portion 18 are limited in order to prevent the printed circuit board 10 from becoming large. Therefore, it is preferable that the extension patterns 17a to 17c are formed so as to ensure the amount of heat received during soldering in the limited insulating portion 18.

### Third Modified Example

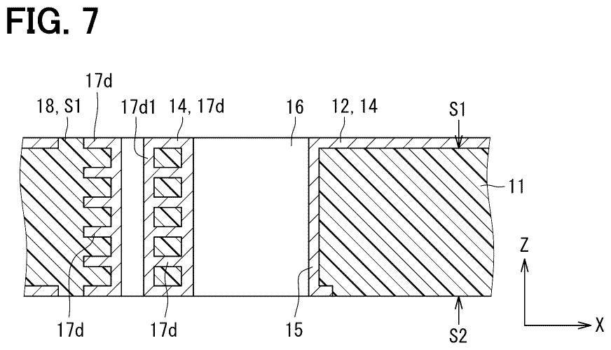

As shown in FIGS. 6 and 7, the extension pattern 17d may be laminated in a plurality of layers with the insulating substrate 11 interposed therebetween. In other words, the printed circuit board 10 is a multi-layer board in which wiring patterns are laminated in multiple layers with insulating substrates 11 interposed therebetween. The extension patterns 17d may be provided on each layer of the printed circuit board 10.

Furthermore, the laminated extension patterns 17d may be electrically connected to each other via an interlayer connection portion 17d1. The interlayer connection portion 17d1 is provided on the insulating substrate 11 and is connected to the extension pattern 17d of each layer. The interlayer connection portion 17d1 is a so-called Via hole.

### Second Embodiment

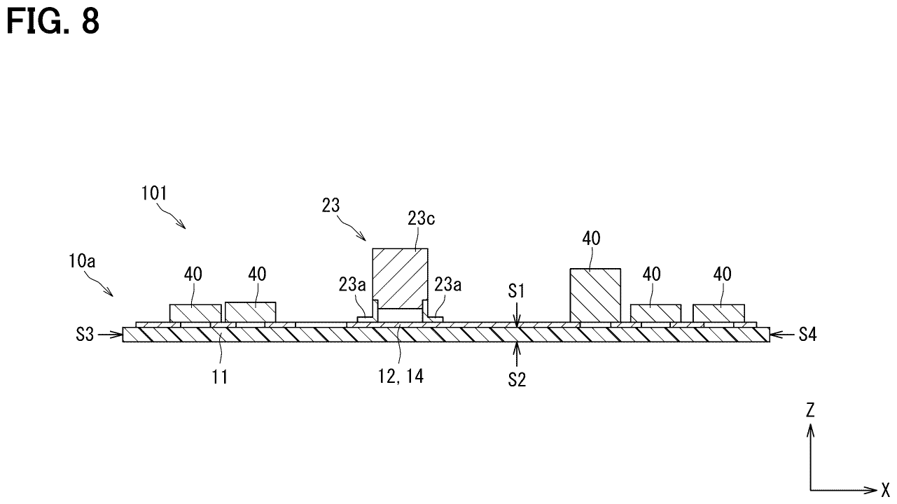

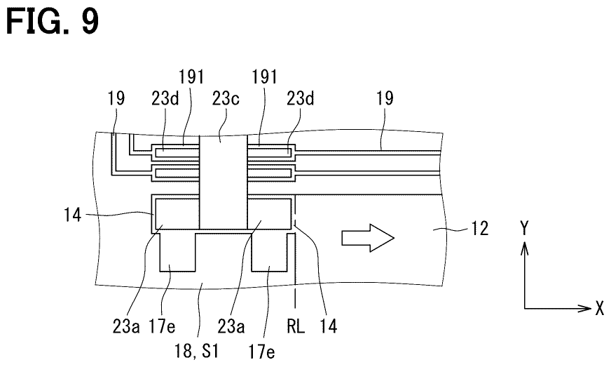

An electronic control device 101 and a printed circuit board 10a according to the second embodiment will be described with reference to FIGS. 8 and 9. FIG. 8 is a cross-sectional view corresponding to FIG. 2. FIG. 9 is a partial plan view of an area including the terminal lands 14. The electronic control device 101 differs from the electronic control device 100 mainly in that the electronic control device 101 includes a board-to-board connector 23. Furthermore, the printed circuit board 10 a differs from the printed circuit board 10 mainly in the configuration of the terminal lands 14.

The electronic control device 101 includes a printed circuit board 10a. On the printed circuit board 10a, the board-to-board connector 23 is mounted instead of the connectors 21 and 22. The board-to-board connector 23 is a connector that electrically connects the printed circuit boards arranged opposite each other.

As shown in FIGS. 8 and 9, the printed circuit board 10a is provided with the power supply pattern 12 which is a part of the solid pattern, similar to the above embodiment. Moreover, the printed circuit board 10a is provided with an insulating portion 18 on the first surface S1 where no solid pattern is formed. The electronic components 40 are mounted on the printed circuit board 10a.

As shown in FIGS. 8 and 9, the board-to-board connector 23 includes a power supply terminal 23a, a connector case 23c, and a signal terminal 23d. The connector case 23c holds the power supply terminal 23a and the signal terminal 23d such that a part of the power supply terminal 23a and a part of the signal terminal 23d are exposed. Unlike the connectors 21 and 22, the board-to-board connector 23 is a surface-mounted type connector. The board-to-board connector 23 corresponds to a surface-mounted component.

As shown in FIG. 9, the printed circuit board 10a is provided with a signal pattern 19 which is a part of the wiring pattern. The signal pattern 19 is connected to a signal land 191 in series. The signal land 191 is connected to the signal terminal 23d. The signal land 191 can also be called a signal pad.

Furthermore, the printed circuit board 10a has the terminal land 14 provided on the first surface S1. The terminal land 14 is connected to a power supply terminal 23a. In other words, the terminal land 14 is a land for surface mounting. The terminal land 14 can also be called a terminal pad.

The terminal land 14 is a portion to which the solder 50 is connected, similarly to the above embodiment. The terminal land 14 is provided such that a part of the terminal land 14 is continuous with the solid pattern and another part of the terminal land 14 is adjacent to the insulating portion 18. Here, as an example, the terminal land 14 provided in continuity with the power supply pattern 12 is used. Furthermore, the printed circuit board 10a is surrounded by the insulating portion 18 and is provided with a conductive extension pattern 17e that extends from the terminal land 14.

The electronic control device 101 can achieve the same effects as the electronic control device 100.

Although the present disclosure has been described in accordance with the embodiments, it is understood that the present disclosure is not limited to such embodiments or structures. The present disclosure encompasses various modifications and variations within the scope of equivalents. In addition, while various combinations and modes are described in the present disclosure, other combinations and modes including only one element, more elements, or less elements therein are also within the scope and spirit of the present disclosure.

### Embodiments of Technical Features

This description discloses a plurality of technical features described in a plurality of sections listed below. Some features may be presented in a multiple dependent form in which a subsequent feature refers to the preceding features selectively. Further, some features may be described in a multiple dependent form referring to another multiple dependent form that depends on features of other multinomial dependent forms. These features written in the multiple dependent form define a plurality of technical features.

### Technical Feature 1:

A printed circuit board includes an insulating substrate (11), a solid pattern (12, 13) which is a part of a conductive wiring portion and is provided on at least one surface of the insulating substrate, a non-formed portion (18) provided on the one surface where no solid pattern is formed, an electrode connection portion (14) which is a portion to which the solder (50) is connected, a portion of which is connected to the solid pattern and another portion of which is adjacent to the non-formed portion, and a conductive extension pattern (17a to 17e) which is surrounded by the non-formed portion and extends from the electrode connection portion.

### Technical Feature 2:

In the printed circuit board according to the technical feature 1, a width (WW) of the solid pattern is wider than a width (LW) of a portion of the electrode connection portion that is continuous with the solid pattern.

### Technical Feature 3:

In the printed circuit board according to the technical feature 1 or 2, a plurality of the extension patterns are provided to extend from the electrode connection portion.

### Technical Feature 4:

In the printed circuit board according to the technical feature 3, the plurality of extension patterns are provided radially.

### Technical Feature 5:

In the printed circuit board according to any one of the technical features 1 to 4,
the solid pattern is electrically connected to an electronic component and is provided on the electronic component side relative to the electrode connection portion, and
the non-formed portion is provided on an opposite side of the electrode connection portion from the electronic component.

### Technical Feature 6:

In the printed circuit board according to the technical feature 5, the electronic component is a power supply circuit.

### Technical Feature 7:

In the printed circuit board according to the technical feature 5, the electronic component is a drive circuit.

### Technical Feature 8:

In the printed circuit board according to any one of the technical features 1 to 7,
the insulating substrate has a through hole (16) formed from the one surface to the opposite surface of the one surface, and
the electrode connection portion is provided on the one surface around the through hole and is connected to a terminal of an insertion-mounted component.

### Technical Feature 9:

In the printed circuit board according to any one of the technical features 1 to 7, the electrode connection portion is provided on the one surface and is connected to a terminal of a surface-mounted component.

### Technical Feature 10:

In the printed circuit board according to any one of the technical features 1 to 9, the extension pattern is laminated in a plurality of layers with the insulating substrate interposed therebetween.

### Technical Feature 11:

The printed circuit board according to the technical feature 10 has an interlayer connection portion (17d1) that is provided on the insulating substrate and electrically connects the laminated extension patterns.

### Technical Feature 12:

An electronic control device includes a printed circuit board (10) and an electronic component (40) mounted on the printed circuit board.

The printed circuit board includes an insulating substrate (11), a solid pattern (12, 13) which is a part of a conductive wiring portion and is provided on at least one surface of the insulating substrate, a non-formed portion (18) on one surface where no solid pattern is formed, an electrode connection portion (14) which is a portion to which the solder (50) is connected, a portion of which is connected to the solid pattern and another portion of which is adjacent to the non-formed portion, and a conductive extension pattern (17a to 17e) which is surrounded by the non-formed portion and extends from the electrode connection portion.

The electronic component is electrically connected to the wiring portion.

What is claimed is:

1. A printed circuit board, comprising:
an insulating substrate;
a solid pattern which is a part of a conductive wiring portion and is provided on at least one surface of the insulating substrate;
a non-formed portion provided on the one surface where no solid pattern is formed;
an electrode connection portion which is a portion to which a solder is connected, a portion of which is connected to the solid pattern and another portion of which is adjacent to the non-formed portion; and
a conductive extension pattern which is surrounded by the non-formed portion and extends from the electrode connection portion.

2. The printed circuit board according to claim 1, wherein
a width of the solid pattern is wider than a width of a portion of the electrode connection portion that is continuous with the solid pattern.

3. The printed circuit board according to claim 1, wherein
a plurality of the extension patterns are provided to extend from the electrode connection portion.

4. The printed circuit board according to claim 3, wherein
the plurality of extension patterns are provided in a radial pattern.

5. The printed circuit board according to claim 1, wherein
the solid pattern is electrically connected to an electronic component and is provided on an electronic component side relative to the electrode connection portion, and
the non-formed portion is provided on an opposite side of the electrode connection portion from the electronic component.

6. The printed circuit board according to claim 5, wherein
the electronic component is a power supply circuit.

7. The printed circuit board according to claim 5, wherein
the electronic component is a driving circuit.

8. The printed circuit board according to claim 1, wherein
the insulating substrate has a through hole formed from the one surface to an opposite surface of the one surface, and
the electrode connection portion is provided on the one surface around the through hole and is connected to a terminal of an insertion-mounted component.

9. The printed circuit board according to claim 1, wherein
the electrode connection portion is provided on the one surface and is connected to a terminal of a surface-mounted component.

10. The printed circuit board according to claim 1, wherein
the extension patterns are laminated in a plurality of layers with the insulating substrate interposed therebetween.

11. The printed circuit board according to claim 10, further comprising,
an interlayer connection portion that is provided on the insulating substrate and electrically connects the laminated extension patterns.

12. An electronic control device, comprising:
a printed circuit board; and
an electronic component mounted on the printed circuit board, wherein
the printed circuit board includes
an insulating substrate,
a solid pattern which is a part of a conductive wiring portion and is provided on at least one surface of the insulating substrate,
a non-formed portion on one surface where no solid pattern is formed,
an electrode connection portion which is a portion to which the solder is connected, a portion of which is connected to the solid pattern and another portion of which is adjacent to the non-formed portion, and
a conductive extension pattern which is surrounded by the non-formed portion and extends from the electrode connection portion, and
the electronic component is electrically connected to the wiring portion.
